(19) United States
(12) Patent Application Publication
(10) Pub. No.: US 2024/0173815 A1
(43) Pub. Date: May 30, 2024

(54) CHEMICAL MECHANICAL POLISHING APPARATUS

(71) Applicant: SAMSUNG ELECTRONICS CO., LTD., Suwon-si (KR)

(72) Inventor: DONGHOON KWON, Suwon-si (KR)

(73) Assignee: SAMSUNG ELECTRONICS CO., LTD., Suwon-si (KR)

(21) Appl. No.: 18/201,967

(22) Filed: May 25, 2023

(30) Foreign Application Priority Data
Nov. 29, 2022 (KR) 10-2022-0162636

(51) Int. Cl. B24B 37/24; B24B 1/00

(52) U.S. Cl. CPC B24B 37/24; B24B 1/005

(57) ABSTRACT

A chemical mechanical polishing apparatus includes a polishing platen that includes an electromagnet and is rotatable; a lower polishing pad that is positioned on the polishing platen, the lower polishing pad including a first area and a second area, the first area including a first magnetic material and the second area including a non-magnetic material, wherein the first area overlaps the electromagnet; an upper polishing pad that is positioned on the lower polishing pad, includes a second magnetic material, and overlaps the first area; and a polishing head configured to provide a wafer on the upper polishing pad and is rotatable.

### CROSS-REFERENCE TO RELATED APPLICATION

This application is based on and claims priority under 35 U.S.C. § 119 to Korean Patent Application No. 10-2022-0162636 filed in the Korean Intellectual Property Office on Nov. 29, 2022, the entire contents of which are incorporated herein by reference.

### BACKGROUND

### 1 Field

The disclosure relates to a chemical mechanical polishing apparatus.

### 2. DESCRIPTION OF RELATED ART

In a manufacturing process of a semiconductor device, a chemical mechanical polishing (CMP) process is widely used as a planarization technique for removing a step between films formed on a substrate. The chemical mechanical polishing process may efficiently planarize films formed on a substrate by injecting a slurry composition containing polishing particles between the substrate and a polishing pad and causing friction between the substrate and the polishing pad.

### SUMMARY

Embodiments provide a chemical mechanical polishing apparatus that may efficiently polish a wafer.

In accordance with an aspect of the disclosure, a chemical mechanical polishing apparatus includes a polishing platen comprising an electromagnet, wherein the polishing platen is rotatable; a lower polishing pad positioned on the polishing platen, the lower polishing pad including a first area and a second area, the first area including a first magnetic material, and the second area including a non-magnetic material, wherein the first area overlaps the electromagnet; an upper polishing pad on the lower polishing pad, the upper polishing pad including a second magnetic material, and the upper polishing pad overlapping the first area; and a polishing head configured to provide a wafer on the upper polishing pad, wherein the polishing head is rotatable.

In accordance with an aspect of the disclosure, a chemical mechanical polishing apparatus includes a polishing platen comprising an electromagnet; a polishing pad on the polishing platen, the polishing pad including a groove; and a polishing head that provides a wafer on the polishing pad, wherein the polishing head is rotatable, wherein a portion of the polishing pad below the groove comprises a non-magnetic material, and wherein portions of the polishing pad at both sides of the groove comprise a magnetic material.

In accordance with an aspect of the disclosure, a chemical mechanical polishing apparatus includes a polishing platen including an electromagnet, wherein the polishing platen is rotatable; a lower polishing pad positioned on the polishing platen, the lower polishing pad including a first area and a second area, wherein the first area includes a first magnetic material and overlaps the electromagnet, and wherein the second area includes a non-magnetic material; an upper polishing pad on the lower polishing pad and overlapping the first area; and a polishing head that provides a wafer on the upper polishing pad and is rotatable, wherein an edge of the upper polishing pad is above the second area.

According to embodiments, a chemical mechanical polishing apparatus may include a magnetic material in a first area of a lower polishing pad and in an upper polishing pad, so that a slurry including a magnetic material may be positioned on the upper polishing pad. Accordingly, a wafer may be efficiently polished.

### BRIEF DESCRIPTION OF DRAWINGS

FIG. 1 illustrates a schematic top plan view for explaining polishing equipment including a chemical mechanical polishing apparatus according to an embodiment.

FIG. 2 illustrates a schematic perspective view for explaining a chemical mechanical polishing apparatus according to an embodiment.

FIG. 3 illustrates a schematic cross-sectional view for explaining a chemical mechanical polishing apparatus according to an embodiment.

FIG. 4 illustrates a schematic top plan view for explaining a polishing pad according to an embodiment.

FIG. 5 illustrates an enlarged top plan view of an area S1 of FIG. 4.

FIG. 6 illustrates an enlarged cross-sectional view of an area R of FIG. 3.

FIG. 7 illustrates a schematic diagram of slurry particles of a chemical mechanical polishing apparatus according to an embodiment.

FIG. 8 to FIG. 10 illustrate schematic diagrams of slurry particles of a chemical mechanical polishing apparatus according to embodiments.

FIG. 11 illustrates a cross-sectional view of a polishing method of a chemical mechanical polishing apparatus according to an embodiment.

FIG. 12 to FIG. 15 illustrate enlarged cross-sectional views for explaining a polishing pad of a chemical mechanical polishing apparatus according to embodiments.

### DETAILED DESCRIPTION

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

Parts or portions that are irrelevant to the description are omitted, and identical or similar constituent elements throughout the specification are denoted by the same reference numerals.

Further, in the drawings, the size and thickness of each element are arbitrarily illustrated for ease of description, and the disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present. Like numerals refer to like elements throughout.

Spatially relative terms, such as “over,” “above,” “on,” “upper,” “below,” “under,” “beneath,” “lower,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

For the sake of brevity, conventional elements to semiconductor devices may or may not be described in detail herein for brevity purposes.

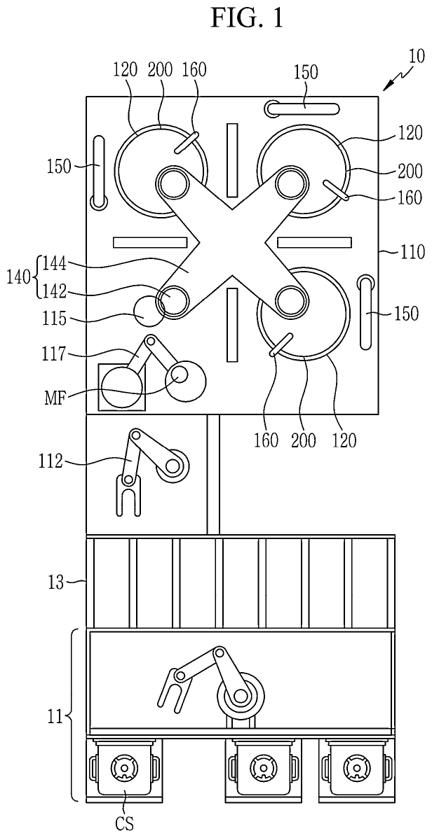

Hereinafter, a chemical mechanical polishing apparatus according to embodiments will be described with reference to FIGS. 1 to 15.

FIG. 1 illustrates a schematic top plan view for explaining polishing equipment including a chemical mechanical polishing apparatus according to an embodiment.

Referring to FIG. 1, the polishing facility according to an embodiment may include a chemical mechanical polishing apparatus 10, an index part 11, a transfer robot 112, and a cleaning apparatus 13.

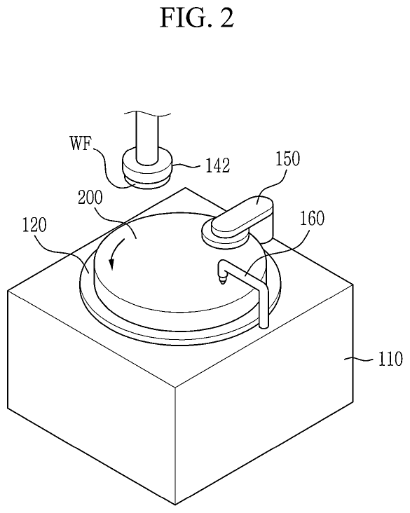

The chemical mechanical polishing apparatus 10 may polish a wafer WF. In an embodiment, the chemical mechanical polishing apparatus 10 may include a lower base 110, a load cup 115, a polishing platen 120, a polishing pad 200, a carrier head assembly 140, a pad conditioner 150, and a slurry supplier 160. The chemical mechanical polishing apparatus 10 will be described later in more detail with reference to FIGS. 2 to 6.

The index part 11 may provide a space in which a cassette CS in which the wafers WF are accommodated is placed. The index part 11 may take out the wafer WF from the cassette CS and transfer it to the transfer robot 112, or may carry the wafer WF of which a polishing process has been completed into the cassette CS.

The transfer robot 112 may be disposed between the chemical mechanical polishing apparatus 10 and the index part 11. The transfer robot 112 may transfer the wafer WF between the chemical mechanical polishing apparatus 10 and the index part 11. Illustratively, the load cup 115 adjacent to the transfer robot 112 may be disposed in the chemical mechanical polishing apparatus 10. The load cup 115 may provide a space for the wafer WF to temporarily stand by. In addition, an exchanger 117 may be disposed between the transfer robot 112 and the load cup 115. The exchanger 117 may transfer the wafer WF transferred from the index part 11 by the transfer robot 112 to the load cup 115, or may transfer the wafer WF disposed on the load cup 115 to the transfer robot 112.

The cleaning apparatus 13 may be disposed between the index part 11 and the transfer robot 112. The wafer WF polished in the chemical mechanical polishing apparatus 10 may be disposed on the load cup 115. The wafer WF disposed on the load cup 115 may be transferred to the cleaning apparatus 13 by the transfer robot 112 disposed adjacent to the load cup 115. The cleaning apparatus 13 may clean contaminants remaining on the polished wafer WF. The cleaned wafer WF may be transferred to the index part 11 and accommodated in the cassette CS. Accordingly, the polishing process for the wafer WF may be completed.

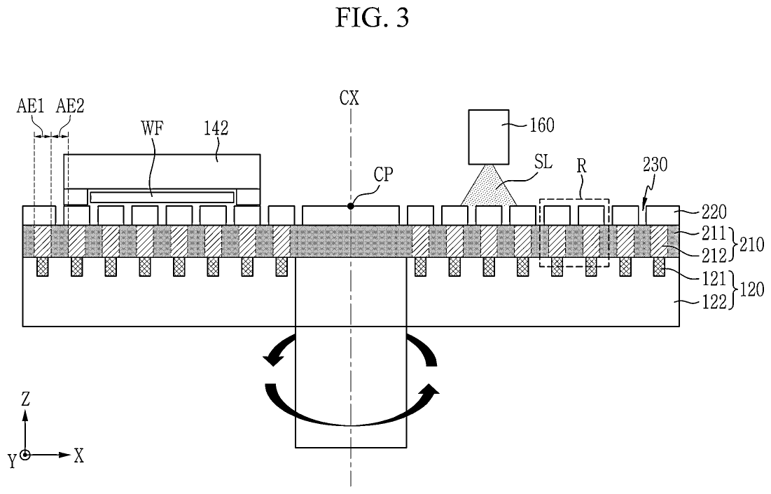

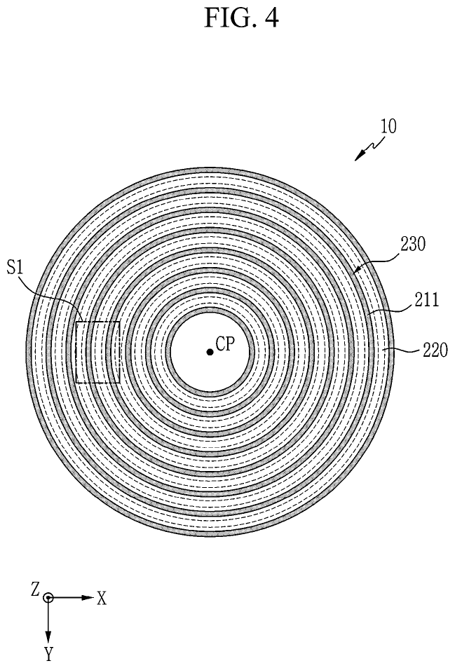

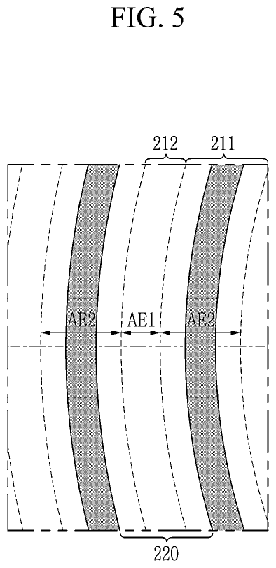

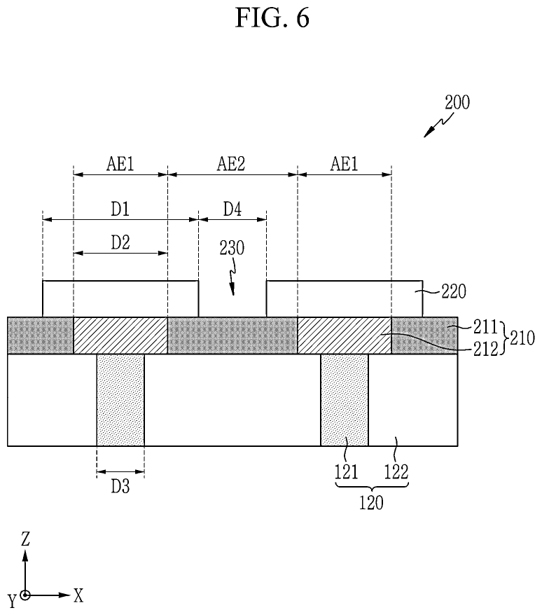

FIG. 2 illustrates a schematic perspective view for explaining a chemical mechanical polishing apparatus according to an embodiment. FIG. 3 illustrates a schematic cross-sectional view for explaining a chemical mechanical polishing apparatus according to an embodiment. FIG. 4 illustrates a schematic top plan view for explaining a polishing pad according to an embodiment. FIG. 5 illustrates an enlarged top plan view of an area S1 of FIG. 4. FIG. 6 illustrates an enlarged cross-sectional view of an area R of FIG. 3.

Hereinafter, the chemical mechanical polishing apparatus will be described with reference to FIGS. 1 to 6.

First, referring to FIGS. 1 to 3, the chemical mechanical polishing apparatus according to an embodiment may include the lower base 110, the load cup 115, the polishing platen 120, the polishing pad 200, the carrier head assembly 140, the pad conditioner 150, and the slurry supplier 160.

The lower base 110 may provide a lower structure of the chemical mechanical polishing apparatus according to the embodiment. For example, the lower base 110 may support the load cup 115, the polishing platen 120, the polishing pad 200, the carrier head assembly 140, the pad conditioner 150, and the slurry supplier 160 to be described later.

The polishing platen 120 may be disposed on an upper surface of the lower base 110. The polishing platen 120 may be rotatable. For example, the polishing platen 120 may be rotated by receiving rotational power from a motor disposed in the lower base 110. The polishing platen 120 may be rotated around a first axis CX (see, e.g., FIG. 3) perpendicular to the upper surface of the polishing platen 120. Here, the first axis CX may be a direction extending along a third direction (Z-axis direction).

The polishing platen 120 includes an electromagnet 121 and a platen member 122.

The platen member 122 may provide a lower structure of the polishing platen 120. The electromagnet 121 may be accommodated in a trench formed on an upper surface of the platen member 122.

The electromagnets 121 may be disposed to be spaced apart from each other on the platen member 122. For example, the electromagnets 121 may be disposed to be spaced apart from each other along a circumferential direction from the first axis CX. In addition, when the platen member 122 has a circular shape in a plan view, each of a plurality of electromagnets 121 may have a ring shape. In this case, the plurality of electromagnets 121 may be disposed to be spaced apart from each other along the circumferential direction from the first axis CX. Here, the first axis CX may be a direction extending from a center CP of the polishing pad along the third direction (Z-axis direction). The plurality of electromagnets 121 may be spaced apart from each other at regular intervals. However, the disclosure is not limited thereto, and the interval between the plurality of electromagnets 121 may not be constant.

The electromagnet 121 may generate magnetic force. The electromagnet 121 may be a magnetic material that generates magnetic force when a current flows therethrough and does not generate magnetic force when no current flows therethrough. For example, the electromagnet 121 may generate magnetic force around the electromagnet 121 by receiving a current. Alternatively, the electromagnet 121 may be replaced with a permanent magnet or a ferromagnetic material. However, the disclosure is not limited thereto, and the electromagnet 121 may be replaced with other materials generating magnetic force.

In an embodiment, a plurality of the polishing platens 120 may be provided on the lower base 110. Illustratively, as shown in FIG. 1, the plurality of the polishing platens 120 may be disposed to be spaced apart from each other at predetermined intervals based on a center of the lower base 110.

The polishing pad 200 may be disposed on the upper surface of the polishing platen 120. The polishing pad 200 may be supported by the polishing platen 120 to be rotated. An upper surface of the polishing pad 200 may be formed as a planar surface parallel to a first direction (X-axis direction) and a second direction (Y-axis direction). The polishing pad 200 may have a constant thickness in the third direction (Z-axis direction) perpendicular to the first direction (X-axis direction) and the second direction (Y-axis direction). The polishing pad 200 may be provided as a circular plate, but is not limited thereto.

The polishing pad 200 may include a polishing surface having predetermined roughness. While the chemical mechanical polishing process is being performed, the polishing surface of the polishing pad 200 directly contacts the wafer WF to mechanically polish the wafer WF. In an embodiment, the polishing surface may be the upper surface of the polishing pad 200.

The polishing pad 200 may include a porous material having a plurality of microspaces. The microspaces of the polishing pad 200 may accommodate a slurry SL provided while the chemical mechanical polishing process is performed.

A lower polishing pad 210 may be supported by the polishing platen 120 to be rotated. The lower polishing pad 210 may be provided as a plate having a certain thickness, for example, a circular plate, but is not limited thereto.

Further referring to FIGS. 4 and 5, the lower polishing pad 210 includes a first-sub polishing pad 212 and a second sub-polishing pad 211. For example, the lower polishing pad 210 may include a first sub-polishing pad 212 including a magnetic material and a second sub-polishing pad 211 including a non-magnetic material.

The first sub-polishing pad 212 and the second sub-polishing pad 211 may be alternately disposed. For example, as in the case of FIG. 4, the first sub-polishing pad 212 and the second sub-polishing pad 211 may be alternately disposed along the circumferential direction from the first axis CX. In addition, when the lower polishing pad 210 has a circular shape, the first sub-polishing pad 212 and the second sub-polishing pad 211 may be alternately disposed along the circumferential direction from the center CP of the polishing pad in a ring shape, respectively. Here, the first axis CX may be a direction extending from the center CP of the polishing pad along the third direction (Z-axis direction).

FIG. 4 and FIG. 5 illustrate that eight first sub-polishing pads 212 and eight second sub-polishing pads 211 are alternately disposed, but the numbers of the first sub-polishing pads 212 and the second sub-polishing pads 211 are not limited thereto.

Further referring to FIG. 6, the lower polishing pad 210 includes a first area AE1 and a second area AE2. For example, the lower polishing pad 210 may include the first area AE1 in which the first sub-polishing pad 212 is positioned and the second area AE2 in which the second sub-polishing pad 211 is positioned.

The first area AE1 and the second area AE2 may be alternately disposed. In addition, the first area AE1 and the second area AE2 of the lower polishing pad 210 may contact each other. For example, the first area AE1 and the second area AE2 of the lower polishing pad 210 may be adjacent to each other, and may be alternately disposed along a direction away from the center CP of the polishing pad.

The first area AE1 may overlap the electromagnet 121. For example, a second width D2 of the first area AE1 may be larger than a third width D3 of the electromagnet 121. In addition, the first area AE1 may cover the electromagnet 121. The upper surface of the electromagnet 121 may be covered by the first area AE1 of the lower polishing pad 210. Accordingly, the electromagnet 121 overlaps a portion of the first area AE1, and each edge of the electromagnet 121 may be positioned under the first area AE1.

The first area AE1 may include a first magnetic material. The first magnetic material may include a magnetic polymer. For example, the first magnetic material may be made of a magnetic polymer, or may include a material obtained by synthesizing a magnetic polymer and polyurethane. The magnetic polymer may include a material in which polyaniline (or emeraldine-based polyaniline) and tetracyanoquinodimethane are combined. Alternatively, it may include Fe₃O₄ or CoFe₂O₄.

Alternatively, the first magnetic material may include magnetic particles. For example, the first magnetic material may include Fe₃O₄ or CoFe₂O₄. However, it is not limited thereto, and the first magnetic material may include ferromagnetic particles such as Fe₂O₃, FeOFe₂O₃, NiOFe₂O₃, CuOFe₂O₃, MgOFe₂O₃, MnBi, MnSb, MnOFe₂O₃, Y₃Fe₅O₁₂, CrO₂, MnAs, and EuO, as well as Fe, Ni, Co, Gd, Dy, and alloys of these metals. This magnetic material or magnetic polymer may transmit the magnetic force generated from the electromagnet to the first area AE1.

The second area AE2 may overlap the platen member 122. For example, a width of the second area AE2 may be smaller than that of the platen member 122. In addition, a portion of the upper surface of the platen member 122 may be covered by the second area AE2. Accordingly, the second area AE2 may overlap a portion of the platen member 122, and the second area AE2 may not overlap the electromagnet 121.

The second area AE2 may include a different material from that of the first area AE1. For example, the second area AE2 may be made of a non-magnetic material. The second area AE2 of the lower polishing pad 210 may include polyurethane, but is not limited thereto.

In summary, the first area AE1 of the lower polishing pad 210 may be an area including the first magnetic material, and may be an area in which the first sub polishing pad 212 is positioned. In addition, the second area AE2 of the lower polishing pad 210 may be an area including a non-magnetic material, and may be an area in which the second sub-polishing pad 211 is positioned.

A plurality of upper polishing pads 220 are positioned on the lower polishing pad 210.

The plurality of upper polishing pads 220 may be spaced apart from each other. For example, the upper polishing pads 220 may be spaced apart from each other in a circumferential direction from the center CP of the polishing pad. In addition, when the lower polishing pad 210 has a circular shape, as shown in FIG. 4, the upper polishing pads 220 may be disposed to be spaced apart from each other along the circumferential direction from the center CP of the polishing pad in a ring shape, respectively. Here, the first axis CX (see, e.g., FIG. 3) may be a direction extending from the center CP of the polishing pad along the third direction (Z-axis direction).

The upper polishing pad 220 may overlap the first area AE1. For example, a first width D1 of the upper polishing pad 220 may be larger than the second width D2 of the first area AE1 of the lower polishing pad 210. In addition, the upper polishing pad 220 may cover the first area AE1. Accordingly, the first area AE1 may overlap a portion of the upper polishing pad 220, and the upper polishing pad 220 may be positioned on an edge of the first area AE1. However, FIG. 6 illustrates that the first width D1 of the upper polishing pad 220 is larger than the second width D2 of the first area AE1, but the embodiment is not limited thereto, and the first width D1 of the upper polishing pad 220 may be the same as the second width D2 of the first area AE1.

The plurality of upper polishing pads 220 may be disposed to be spaced apart from each other while covering the first area AE1 of the lower polishing pad 210. The edge of the upper polishing pad 220 may be positioned on the second area AE2 of the lower polishing pad 210. In other words, the upper polishing pad 220 may overlap some of the second area AE2, and may not overlap the other some thereof.

In addition, the upper polishing pad 220 may overlap the electromagnet 121. For example, the first width D1 of the upper polishing pad 220 may be larger than the third width D3 of the electromagnet 121. In addition, the upper polishing pad 220 may cover the electromagnet 121. Accordingly, the electromagnet 121 overlaps a portion of the upper polishing pad 220, and an edge of the electromagnet 121 may be positioned under the upper polishing pad 220 as shown, e.g., in FIG. 6.

The upper polishing pad 220 may include a second magnetic material. The second magnetic material may include a magnetic polymer. For example, the second magnetic material may be made of a magnetic polymer, or may include a material obtained by synthesizing a magnetic polymer and polyurethane. The magnetic polymer may include a material in which polyaniline (or emeraldine-based polyaniline) and tetracyanoquinodimethane are combined. Alternatively, it may include Fe₃O₄ or CoFe₂O₄.

Alternatively, the second magnetic material may include magnetic particles. For example, the second magnetic material may include Fe₃O₄ or CoFe₂O₄. However, it is not limited thereto, and the second magnetic material may include ferromagnetic particles such as Fe₂O₃, FeOFe₂O₃, NiOFe₂O₃, CuOFe₂O₃, MgOFe₂O₃, MnBi, MnSb, MnOFe₂O₃, Y₃Fe₅O₁₂, CrO₂, MnAs, and EuO, as well as Fe, Ni, Co, Gd, Dy, and alloys of these metals. This magnetic material or magnetic polymer may transmit the magnetic field generated from the electromagnet to the upper polishing pad 220.

The second magnetic material may further include more magnetic particles or magnetic polymers than the first magnetic material. For example, when both the first magnetic material and the second magnetic material include a magnetic polymer, the concentration of the magnetic polymer included in the first magnetic material may be lower than the concentration of the magnetic polymer included in the second magnetic material. However, the embodiment is not limited thereto, and the concentration of magnetic particles or magnetic polymers included in the first magnetic material may be higher than the concentration of magnetic particles or magnetic polymers included in the second magnetic material.

A groove 230 may be disposed between adjacent ones of the plurality of upper polishing pads 220. The plurality of upper polishing pads 220 may cover the first area AE1 of the lower polishing pad 210, and may be disposed to be spaced apart from each other. The edges of the upper polishing pads 220 may be positioned on the second area AE2. In other words, the upper polishing pad 220 may overlap some of the second area AE2, and may not overlap other portions thereof. Accordingly, the groove 230 may be disposed in an area in which the upper polishing pad 220 does not overlap the second area AE2. That is, the groove 230 may expose at least a portion of the second area AE2 of the lower polishing pad 210. A fourth width D4 of the groove 230 may be smaller than the first width D1 of the upper polishing pad 220. That is, the fourth width D4 of the groove 230 may be smaller than a width between adjacent grooves 230.

Accordingly, the groove 230 may be positioned within the second area AE2. In addition, the groove 230 may be surrounded by the second sub-polishing pad 211 and the upper polishing pad 220. For example, a lower side of the groove 230 may be formed with (e.g., defined by) the second sub-polishing pad 211, and both sides of the groove 230 may be formed with (e.g., defined by) sides of adjacent ones of the upper polishing pads 220. That is, the lower side of the groove 230 may include a non-magnetic material, and both sides of the groove 230 may include the second magnetic material.

The carrier head assembly 140 may be disposed on the lower base 110. The carrier head assembly 140 may include a polishing head 142 and an upper base 144 (see, e.g., FIG. 1).

The polishing head 142 may provide the wafer WF on the polishing pad 200. For example, the polishing head 142 may provide the wafer WF so that a polishing target surface of the wafer WF faces a polishing surface (an upper surface) of the polishing pad 200. The polishing head 142 may accommodate the wafer WF, for example, in a vacuum suction method, but embodiments are not limited thereto.

While the chemical mechanical polishing process is being performed, the polishing head 142 may move in the third direction (Z-axis direction) to press the wafer WF on the polishing pad 200. Illustratively, the polishing head 142 is operated in the third direction (Z-axis direction) by using a pneumatic or hydraulic cylinder, so that it is possible to pressurize the wafer WF. While the chemical mechanical polishing process is being performed, the polishing head 142 may be rotated. For example, the polishing head 142 may rotate by receiving rotational power from a motor. For example, the polishing head 142 may be rotated around a rotation axis perpendicular to the upper surface of the polishing pad 200. Accordingly, the wafer WF may be polished by the polishing pad 200.

A polishing head 142 may be disposed on each polishing platen 120 by the upper base 144. Illustratively, as shown in FIG. 1, the upper base 144 may have a shape in which two rods cross each other (for example, a cross (or X) shape). A polishing head 142 may be disposed at at least one end of each of the rods of the upper base 144. As the upper base 144 rotates, the polishing head 142 may sequentially move from the load cup 115 to each polishing platen 120. For example, the polishing head 142 may load the wafer WF from the load cup 115, and then it may be moved to the polishing platen 120 to polish the wafer WF. In addition, the polishing head 142 may upload the polished wafer WF in the load cup 115.

The pad conditioner 150 may be disposed adjacent to the polishing pad 200. The pad conditioner 150 may perform a conditioning process on the polishing pad 200. Accordingly, the pad conditioner 150 may stably maintain a state of the polishing surface of the polishing pad 200 so that the wafer WF is effectively polished during the chemical mechanical polishing process.

The slurry supplier 160 may be disposed adjacent to the polishing pad 200. While the chemical mechanical polishing process is being performed, the slurry supplier 160 may supply the slurry onto the polishing pad 200.

The slurry supplier 160 may include an injection nozzle and a pipe for transporting the slurry. The injection nozzle may be disposed adjacent to the polishing pad 200. Accordingly, the slurry may be supplied onto the polishing pad 200 through the pipe and the injection nozzle.

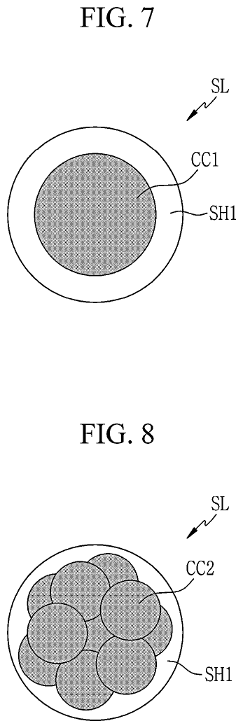

The slurry supplied from the slurry supplier 160 may include, for example, a reaction agent (for example, deionized water for oxidation polishing), a wear particle (for example, silicon dioxide for oxidation polishing), and a chemical reaction catalyst (for example, potassium hydroxide for oxidation polishing), but is not limited thereto. A description of the slurry supplied by the slurry supplier 160 will be described later with reference to FIGS. 7 to 10.

In the chemical mechanical polishing apparatus 10 according to the embodiment, the electromagnet 121 generates magnetic force and the first area AE1 and the upper polishing pad 220 include a magnetic material, so that the magnetic force may be transmitted to the first area AE1 or the upper polishing pad 220. Accordingly, the magnetic material positioned on the upper polishing pad 220 may receive magnetic force, and the magnetic material positioned on the groove 230 may not receive magnetic force.

FIG. 7 illustrates a schematic diagram of slurry particles of a chemical mechanical polishing apparatus according to an embodiment. FIGS. 8 to 10 illustrate schematic diagrams of slurry particles of a chemical mechanical polishing apparatus according to embodiments.

Referring to FIGS. 7 to 10, the slurry SL may have a core-shell structure. For example, the core of the slurry SL may include a third magnetic material, for example, ferromagnetic particles such as Fe₃O₄ or CoFe₂O₄, Fe₂O₃, FeOFe₂O₃, NiOFe₂O₃, CuOFe₂O₃, MgOFe₂O₃, MnBi, MnSb, MnOFe₂O₃, Y₃Fe₅O₁₂, CrO₂, MnAs, and EuO. In addition, the shell of the slurry SL may include polishing particles for polishing the wafer WF. For example, the shell of the slurry SL may include polishing particles such as SiO₂ and CeO₂.

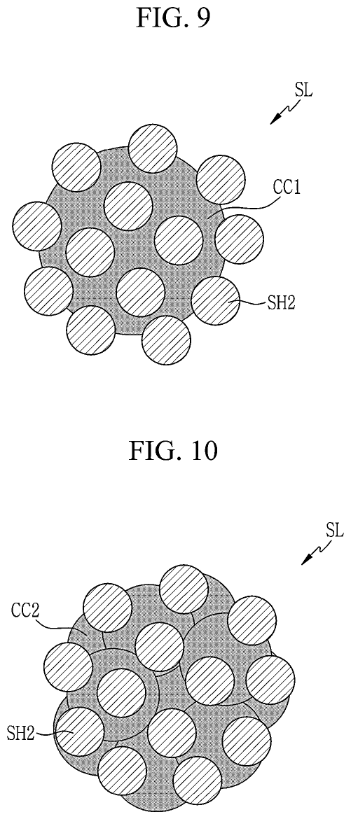

As shown in FIG. 7, a first shell SH1 of the slurry SL may coat a first core CC1 of the slurry SL. In addition, as shown in FIG. 8, a second core CC2 of the slurry SL may have a cluster shape, and the first shell SH1 of the slurry SL may surround the second core CC2. In addition, as shown in FIG. 9, a second shell SH2 of the slurry SL may be formed as a plurality of particles on a surface of the first core CC1. That is, the second shell SH2 of the slurry SL may be discontinuously dispersed on the surface of the first core CC1. In addition, as shown in FIG. 10, the second shell SH2 of the slurry SL may be formed as a plurality of particles on a surface of the second core CC2. That is, the second shell SH2 of the slurry SL may be discontinuously dispersed on the surface of the second core CC2 formed as a cluster.

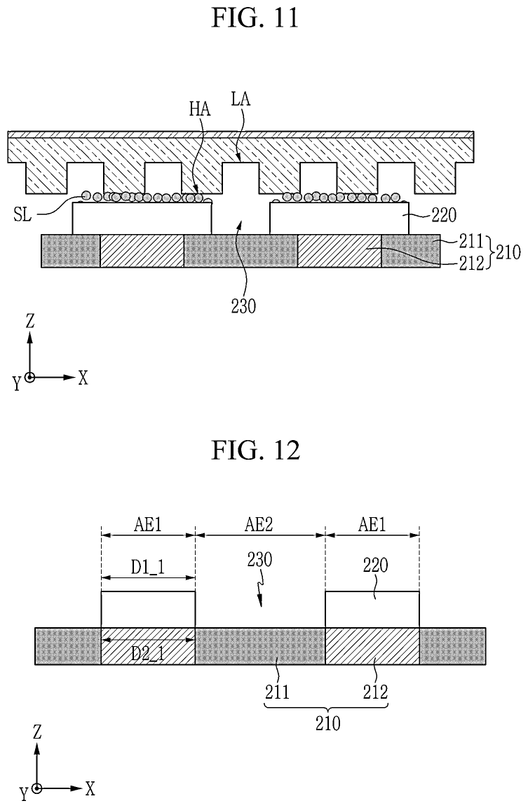

FIG. 11 illustrates a cross-sectional view of a polishing method of a chemical mechanical polishing apparatus according to an embodiment.

Referring to FIG. 11, as described above, the electromagnet 121 generates magnetic force and the first area AE1 and the upper polishing pad 220 include a magnetic material, so that the magnetic force may be transmitted to the first area AE1 or the upper polishing pad 220. That is, a relatively strong magnetic force exists on the upper polishing pad 220, and a relatively weak magnetic force exists on the groove 230.

In addition, since the slurry SL includes the magnetic material and polishing particles, it may be affected by the magnetic force transmitted to the upper polishing pad 220. For example, the magnetic material positioned on the upper polishing pad 220 may receive magnetic force, and the magnetic material positioned on the groove 230 may not receive magnetic force. That is, the slurry SL may be positioned on the upper surface of the upper polishing pad 220, and may not be positioned on the side surface of the upper polishing pad 220 or the second area AE2 of the lower polishing pad 210.

Accordingly, when the slurry SL is supplied from the slurry supplier 160 on the polishing pad 200, the slurry SL may be positioned on the upper polishing pad 220 in which a large magnetic force acts, and the slurry SL may not be positioned on or in the groove 230 in which a small magnetic force acts. Accordingly, when the chemical mechanical polishing apparatus 10 polishes the wafer WF, most of the slurry SL may be disposed between a high step portion HA of the wafer WF to be polished and the polishing pad 200, and relatively little slurry SL may be disposed in the groove 230. Accordingly, the slurry SL may efficiently polish the high step portion HA of the wafer WF while the polishing process is being performed.

In the chemical mechanical polishing apparatus 10 according to the embodiment, the electromagnet 121 generates magnetic force and the first area AE1 and the upper polishing pad 220 include a magnetic material, so that the magnetic force may be transmitted to the first area AE1 and/or the upper polishing pad 220. Accordingly, the slurry SL including the magnetic material is positioned on the upper polishing pad 220, and the high step portion HA of the wafer WF may be efficiently polished.

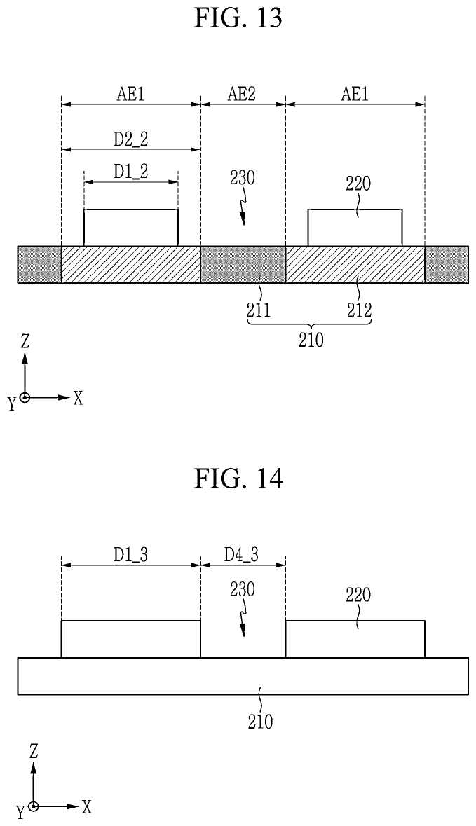

FIGS. 12 and 13 illustrate enlarged cross-sectional views for explaining a polishing pad of a chemical mechanical polishing apparatus according to various embodiments. For better understanding and ease of description, portions overlapping with those described above with reference to FIGS. 1 to 11 are briefly described or omitted.

Referring to FIGS. 12 and 13, the lower polishing pad 210 includes the first-sub polishing pad 212 and the second sub-polishing pad 211. For example, the lower polishing pad 210 may include the first sub-polishing pad 212 including a magnetic material and the second sub-polishing pad 211 including a non-magnetic material.

The lower polishing pad 210 includes the first area AE1 and the second area AE2. For example, the lower polishing pad 210 may include the first area AE1 in which the first sub-polishing pad 212 is positioned and the second area AE2 in which the second sub-polishing pad 211 is positioned.

The first area AE1 may include a first magnetic material. The first magnetic material may include a magnetic polymer. In addition, the second area AE2 may include a different material from that of the first area AE1. For example, the second area AE2 may be made of a non-magnetic material. Descriptions of the first magnetic material and the second magnetic material are substantially the same as those of the embodiment of FIGS. 1 to 6, so will be omitted.

The upper polishing pad 220 is positioned on the lower polishing pad 210.

A plurality of the upper polishing pads 220 may be spaced apart from each other. For example, the upper polishing pads 220 may be spaced apart from each other in a circumferential direction from the center CP of the polishing pad. A description thereof will be omitted since it is substantially the same as the embodiment of FIGS. 1 to 6.

The upper polishing pad 220 may overlap the first area AE1 of the lower polishing pad 210. For example, as shown in FIG. 12, a first width D1_1 of the upper polishing pad 220 may be the same as a second width D2_2 of the first area AE1. Accordingly, the first area AE1 may completely overlap the upper polishing pad 220, and an edge of the first area AE1 may be aligned with an edge of the upper polishing pad 220. Alternatively, as shown in FIG. 13, a first width D1_2 of the upper polishing pad 220 may be smaller than the second width D2_2 of the first area AE1. Accordingly, the edge of the upper polishing pad 220 may be positioned on the first area AE1.

In the chemical mechanical polishing apparatus 10 according to an embodiment, the electromagnet 121 generates magnetic force and the first area AE1 and the upper polishing pad 220 include a magnetic material, so that the magnetic force may be transmitted to the first area AE1 and/or the upper polishing pad 220. Accordingly, the slurry SL including the magnetic material is positioned on the upper polishing pad 220, and the high step portion HA of the wafer WF may be efficiently polished.

FIG. 14 illustrates an enlarged cross-sectional view for explaining a polishing pad of a chemical mechanical polishing apparatus according to an embodiment. For better understanding and ease of description, portions overlapping with those described above with reference to FIGS. 1 to 11 are briefly described or omitted.

Referring to FIG. 14, the lower polishing pad 210 may include a non-magnetic material. For example, the lower polishing pad 210 may include polyurethane, but is not limited thereto.

The upper polishing pad 220 is positioned on the lower polishing pad 210.

The upper polishing pad 220 is spaced apart from the lower polishing pad 210. For example, the upper polishing pads 220 may be disposed to be spaced apart from each other along the circumferential direction. A description thereof will be omitted since it is substantially the same as embodiments of FIGS. 1 to 6.

The upper polishing pad 220 may overlap the lower polishing pad 210. For example, the upper polishing pad 220 may overlap the lower polishing pad 210 by a first width D1_3 of the upper polishing pad 220. In addition, a fourth width D4_3 of the groove 230, which is a distance between adjacent upper polishing pads 220, may be smaller than the first width D1_3 of the upper polishing pad 220.

The upper polishing pad 220 may include a second magnetic material. The second magnetic material may include a magnetic polymer. A description thereof will be omitted since it is substantially the same as embodiments of FIGS. 1 to 6.

The chemical mechanical polishing apparatus 10 according to the embodiment includes the electromagnet 121, the lower polishing pad 210 including a non-magnetic material, and the upper polishing pad 220 including a magnetic material. Even if the lower polishing pad 210 of the chemical mechanical polishing apparatus 10 does not include a magnetic material, since the upper polishing pad 220 includes the magnetic material, the magnetic force generated by the electromagnet 121 may be transmitted to the upper polishing pad 220. Accordingly, the slurry SL including the magnetic material may be positioned on the upper polishing pad 220, and may efficiently polish the wafer WF.

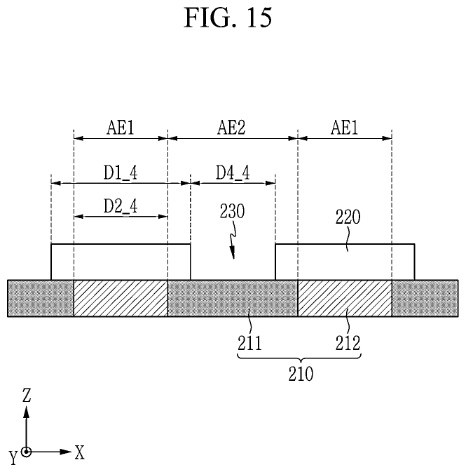

FIG. 15 illustrates an enlarged cross-sectional view for explaining a polishing pad of a chemical mechanical polishing apparatus according to an embodiment. For better understanding and ease of description, portions overlapping with those described above with reference to FIGS. 1 to 11 are briefly described or omitted.

Referring to FIG. 15, the lower polishing pad 210 includes the first-sub polishing pad 212 and the second sub-polishing pad 211. For example, the lower polishing pad 210 may include the first sub-polishing pad 212 including a magnetic material and the second sub-polishing pad 211 including a non-magnetic material.

The lower polishing pad 210 includes the first area AE1 and the second area AE2. For example, the lower polishing pad 210 may include the first area AE1 in which the first sub-polishing pad 212 is positioned and the second area AE2 in which the second sub-polishing pad 211 is positioned. A description thereof will be omitted since it is substantially the same as embodiments of FIGS. 1 to 6.

The first area AE1 may include a first magnetic material. The first magnetic material may include a magnetic polymer. In addition, the second area AE2 may include a material different from that of the first area AE1. For example, the second area AE2 may be made of a non-magnetic material. Descriptions of the first magnetic material and the second magnetic material are substantially the same as those of embodiments of FIGS. 1 to 6, so will be omitted.

The upper polishing pad 220 is positioned on the lower polishing pad 210.

The upper polishing pads 220 may be spaced apart from each other. For example, the upper polishing pads 220 may be disposed to be spaced apart from each other along the circumferential direction. A description thereof will be omitted since it is substantially the same as embodiments of FIGS. 1 to 6.

The upper polishing pad 220 may overlap the first area AE1. For example, a first width D1_4 of the upper polishing pad 220 may be larger than a second width D2_4 of the first area AE1 of the lower polishing pad 210. In addition, the upper polishing pad 220 may cover the first area AE1. Accordingly, the first area AE1 may overlap a portion of the upper polishing pad 220, and an edge of the first area AE1 may be positioned under the upper polishing pad 220.

The upper polishing pad 220 may include a non-magnetic material. For example, the upper polishing pad 220 may include polyurethane, but is not limited thereto.

The chemical mechanical polishing apparatus 10 according to an embodiment includes the electromagnet 121, the lower polishing pad 210 including the first and second areas AE1 and AE2, and the upper polishing pad 220 including a non-magnetic material. Even if the upper polishing pad 220 of the chemical mechanical polishing apparatus 10 does not include a magnetic material, since the first area AE1 of the lower polishing pad 210 includes the magnetic material, the magnetic force generated by the electromagnet 121 may be transmitted to the first area AE1. Accordingly, the slurry SL including the magnetic material may be positioned on the upper polishing pad 220 positioned on the first area AE1, and may efficiently polish the wafer WF.

While this disclosure has been described in connection with what is considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A chemical mechanical polishing apparatus comprising:
a polishing platen comprising an electromagnet, wherein the polishing platen is rotatable;
a lower polishing pad on the polishing platen, the lower polishing pad comprising a first area and a second area, the first area comprising a first magnetic material, and the second area comprising a non-magnetic material, wherein the first area overlaps the electromagnet;
an upper polishing pad on the lower polishing pad, the upper polishing pad comprising a second magnetic material, and the upper polishing pad overlapping the first area; and
a polishing head configured to provide a wafer on the upper polishing pad, wherein the polishing head is rotatable.

2. The chemical mechanical polishing apparatus of claim 1,
wherein a width of the upper polishing pad is larger than or equal to a width of the first area of the lower polishing pad.

3. The chemical mechanical polishing apparatus of claim 2,
wherein the width of the first area of the lower polishing pad is larger than a width of the electromagnet.

4. The chemical mechanical polishing apparatus of claim 1,
wherein the upper polishing pad overlaps the electromagnet.

5. The chemical mechanical polishing apparatus of claim 1,
wherein the electromagnet comprises a permanent magnet or a ferromagnetic material.

6. The chemical mechanical polishing apparatus of claim 5,
wherein the first magnetic material comprises a magnetic polymer.

7. The chemical mechanical polishing apparatus of claim 6,
wherein the first magnetic material comprises a material in which the magnetic polymer and polyurethane are synthesized.

8. The chemical mechanical polishing apparatus of claim 6,
wherein the magnetic polymer comprises a material in which polyaniline and tetracyanoquinodimethane are combined.

9. The chemical mechanical polishing apparatus of claim 1,
wherein the first magnetic material comprises Fe₃O₄ or CoFe₂O₄.

10. The chemical mechanical polishing apparatus of claim 1,
wherein the second magnetic material comprises a magnetic polymer.

11. The chemical mechanical polishing apparatus of claim 1,
wherein the second magnetic material comprises Fe₃O₄ or CoFe₂O₄.

12. The chemical mechanical polishing apparatus of claim 1, further comprising a slurry supplier supplying a slurry on the upper polishing pad, wherein the slurry comprises a third magnetic material.

13. The chemical mechanical polishing apparatus of claim 12, wherein the third magnetic material has a core-shell structure, and
wherein a core of the third magnetic material comprises Fe₃O₄ or CoFe₂O₄.

14. A chemical mechanical polishing apparatus comprising:
a polishing platen comprising an electromagnet;
a polishing pad on the polishing platen, the polishing pad comprising a groove; and
a polishing head that provides a wafer on the polishing pad, wherein the polishing head is rotatable,
wherein a portion of the polishing pad below the groove comprises a non-magnetic material, and
wherein portions of the polishing pad at both sides of the groove comprise a magnetic material.

15. The chemical mechanical polishing apparatus of claim 14,
wherein the magnetic material comprises a magnetic polymer.

16. The chemical mechanical polishing apparatus of claim 15,
wherein the magnetic polymer comprises a material in which polyaniline and tetracyanoquinodimethane are combined.

17. The chemical mechanical polishing apparatus of claim 14,
wherein the polishing pad comprises a plurality of the grooves, and
wherein a width of each of the plurality of grooves is smaller than a width between grooves of the plurality of grooves that are adjacent to each other.

18. A chemical mechanical polishing apparatus comprising:
a polishing platen comprising an electromagnet, wherein the polishing platen is rotatable;
a lower polishing pad positioned on the polishing platen, the lower polishing pad comprising a first area and a second area, wherein the first area comprises a first magnetic material and overlaps the electromagnet, and wherein the second area comprises a non-magnetic material;
an upper polishing pad on the lower polishing pad and overlapping the first area; and
a polishing head that provides a wafer on the upper polishing pad and is rotatable,
wherein an edge of the upper polishing pad is above the second area.

19. The chemical mechanical polishing apparatus of claim 18,
wherein a first width of the upper polishing pad is larger than or equal to a second width of the first area of the lower polishing pad.

20. The chemical mechanical polishing apparatus of claim 18,
wherein the upper polishing pad overlaps the electromagnet.
